(19) United States
(12) Patent Application Publication
(10) Pub. No.: US 2006/0131689 A1
(43) Pub. Date: Jun. 22, 2006

(54) Semiconductor device and fabrication method thereof

(75) Inventor: Yoshikazu Tsukidate, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/062,491

(22) Filed: Feb. 23, 2005

(30) Foreign Application Priority Data
Dec. 17, 2004 (JP) 2004-366605

(51) Int. Cl. H01L 21/76; H01L 29/00

(52) U.S. Cl. 257/506; 438/424; 438/692

(57) ABSTRACT

A semiconductor device includes a device isolation structure formed in a substrate so as to define a device region and a semiconductor device formed in the device region, wherein the device isolation structure includes a device isolation trench formed in the substrate so as to define the device region and a device isolation insulator filling the device isolation trench, the device isolation insulator including a lower part and an upper part, a stepped part being formed between the lower part and the upper part.

### CROSS-REFERENCE TO RELATED APPLICATION

The present application is based on Japanese priority application No. 2004-366605 filed on Dec. 17, 2004, the entire contents of which are hereby incorporated by reference.

### BACKGROUND OF THE INVENTION

The present invention generally relates to semiconductor devices and more particularly to fabrication method of a semiconductor device having an STI device isolation structure and a semiconductor device fabricated according to such a process.

A device isolation structure is used in a semiconductor integrated circuit in which plural semiconductor devices are integrated on a common substrate, for electrically isolating the individual semiconductor devices.

Conventionally, a so-called LOCOS oxide film has been used for such a device isolation structure, while LOCOS oxide film occupies a large area on the substrate, and because of this, recent semiconductor integrated circuits of large integration density generally use a so-called STI (shallow trench isolation) formed of a device isolation trench in the substrate surrounding a device region and a device isolation insulator filling such a device isolation trench.

Reference 1: Japanese Laid-Open Patent Application 9-252049 Official Gazette

### SUMMARY OF THE INVENTION

With such recent ultrafine semiconductor integrated circuits that use an STI device isolation structure, it should be noted that the demand of device miniaturization persists, and thus, there is a continuing demand for reduction of the width of the device isolation trench.

On the other hand, when the width of the device isolation trench is thus reduced so as to meet for the demand for device miniaturization, there arises a need to increase the depth of the device isolation trench at the same time in order to secure sufficient breakdown withstand voltage necessary for device isolation.

For example, in the case of recent ultrafine semiconductor devices having the gate length of 60nm or less, there is a demand that the device isolation trench has a width of 0.1 μm or less, while such a device isolation trench generally has the depth of 250-300 nm.

With such a device isolation trench of large aspect ratio characterized by small trench width and large trench depth, there arises a problem in that it is difficult to fill the device isolation trench with an insulation film, and there tends to arise the problem of increased defect formation caused by poor filling of the device isolation trench with a device isolation film.

FIGS. 1A-1C are diagrams showing the process of formation of such a conventional STI structure.

Referring to FIG. 1A, there is formed an SiN mask film 13 on a silicon substrate 11 via an SiO₂ film (thermal oxide film) 12, wherein it should be noted that, in the state of FIG. 1A, there is formed a device isolation trench 11A in the silicon substrate 11 as a result of a dry etching process conducted while using the SiN mask film 13 as a mask.

Next, with the step of FIG. 1B, an SiO₂ film is deposited on the SiN mask film 13 by a high-density plasma CVD process so as to fill the device isolation trench 11A, and as a result, a device isolation insulator 15 filling the device isolation trench 11A is obtained. Thereby, it should be noted that the deposition of the SiO₂ film 15 on the device isolation trench 11A is started simultaneously from the sidewall surfaces and the bottom surface of the device isolation trench 11A, and thus, there can be a case in which a void 15X is formed in the film 15. It should be noted that such a void 15X may be formed at various locations of the trench 11A of FIG. 1A except for the uppermost part of the trench 11A.

Further, FIG. 1C shows the planarized state of the structure of FIG. 1B in which a part of the SiO₂ film 15 located on the SiN mask film 13 is removed by a CMP process, the SiN mask film 13 is removed by a pyrophosphoric acid treatment, the thermal oxide film 12 is removed by an HF treatment and further the device isolation insulator 15 projecting on the silicon oxide film 11 is subsequently etched by using the HF etchant.

As shown in FIG. 1C, it is generally difficult to control the location of the void 15X in the case the device isolation insulator 15 includes such a void as will be understood from the mechanism of void formation explained before. Thus, there can be a case in which the void 15X is exposed at the surface of the device isolation insulator 15 in the state in which the SiN mask 13 and the thermal oxide film 12 are removed and planarization is applied further as in the case of FIG. 1C.

When such a void 15X or other defects are exposed at the surface of the device isolation insulator 15X, there is a risk that such a defect captures various impurities during the substrate process steps conducted thereafter and there may occur formation of defective semiconductor devices or decrease of yield of device production.

In order to avoid such void formation, it has been necessary to decrease the depth of the device isolation trench 11A and prevent increase of the aspect ratio thereof. However, in the case when such a shallow isolation trench has been used, it becomes difficult to realize satisfactory device isolation performance particularly in the case of semiconductor integrated circuit devices having a large integration density.

In a first aspect, the present invention provides a semiconductor device, comprising:

a substrate;

a device isolation structure formed in said substrate so as to define a device region; and

a semiconductor device formed in said device region,

wherein said device isolation structure comprises a device isolation trench formed in said substrate so as to define said device region and a device isolation insulator filling said device isolation trench,

said device isolation insulator comprising a lower part and an upper part,

a stepped part being formed between said lower part and said upper part.

In another aspect, the present invention provides a method of fabricating a semiconductor device, comprising the steps of:

forming a mask pattern of a first insulation film having an opening on a semiconductor substrate and forming a device isolation trench in said semiconductor substrate in correspondence to said opening while using said mask pattern as a mask;

depositing a second insulation film on said mask pattern so as to fill said device isolation trench;

removing said second insulation film by a chemical mechanical polishing process until said first insulation film is exposed and forming a device isolation insulator by said second insulation film remaining in said device isolation trench;

exposing a surface of said semiconductor substrate by removing said mask pattern; and

growing a semiconductor layer epitaxially on said exposed surface of said semiconductor substrate.

According to the present invention, the device isolation insulator protrudes out from the semiconductor substrate as a result of the process steps of: forming a hard mask pattern, depositing a device isolation insulator so as to fill a device isolation trench, removing the device isolation insulator on the hard mask pattern by a chemical mechanical polishing process, and exposing the surface of the semiconductor substrate by removing the hard mask pattern.

With the present invention, it should be noted that a semiconductor layer is grown epitaxially from the foregoing exposed surface of the semiconductor substrate without planarizing the device isolation insulator thus protruding in the upward direction. With this, it becomes possible to form the active region of the semiconductor device formed on the semiconductor epitaxial layer in the vicinity of a top end part of the protruding device isolation insulator where the probability of existence of the defect 15X is very small. Thereby, it becomes possible to increase the effective depth of the device isolation trench and at the same time increase the yield of semiconductor production significantly.

Further, according to the present invention, it becomes possible to improve the characteristics of the device isolation structure by filling a deep device isolation trench with a device isolation insulator without causing formation of defects such as void.

Other objects and further features of the present invention will become apparent from the following detailed description when read in conjunction with the attached drawings.

### BRIEF DESCRIPTION OF THE DRAWINGS

FIGS. 1A-1C are diagrams showing the process of formation of a conventional STI device isolation structure;

FIGS. 2A-2G are diagrams showing the process of formation of an STI device isolation structure according to a first embodiment of the present invention:

FIG. 3 is a diagram showing a cross-section of the STI device isolation structure according to the first embodiment of the present invention;

FIGS. 4A-4C are diagrams showing the fabrication process of a CMOS device having an STI device isolation structure according to a second embodiment of the present invention;

FIGS. 5A-5H are diagrams showing the process of formation of an STI device isolation structure according to a third embodiment of the present invention;

FIG. 6 is a diagram showing the construction of a CMOS device having an STI device isolation structure according to a fourth embodiment of the present invention;

FIGS. 7A-7H are diagram showing the process of formation of an STI device isolation structure according to a fifth embodiment of the present invention.

### DETAILED DESCRIPTION OF THE INVENTION

### First Embodiment

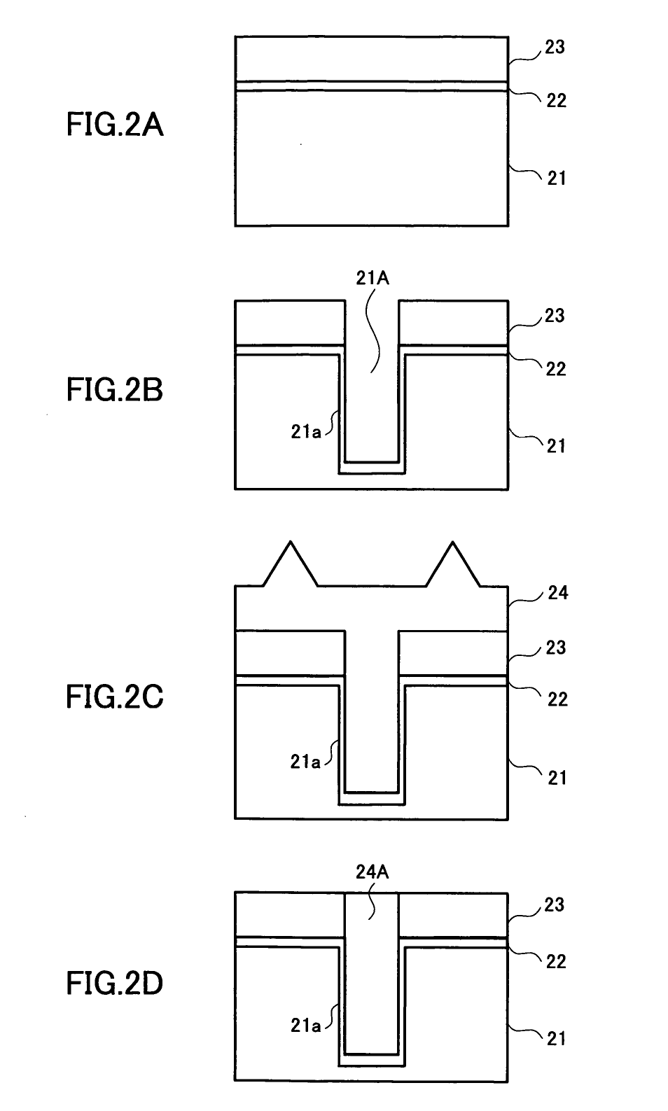

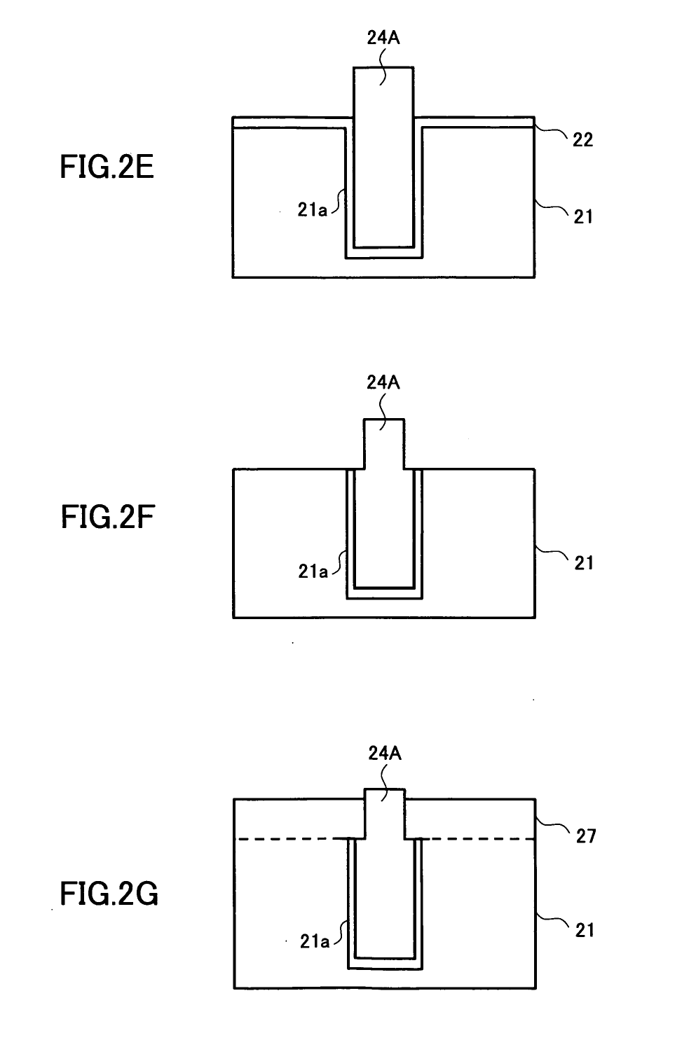

FIGS. 2A-2G are diagrams showing the process of forming a device isolation structure according to a first embodiment of the present invention.

Referring to FIG. 2A, there is formed a thermal oxide film 22 on a silicon substrate 21 typically with the thickness of 10 nm, and a nitride film 23 is formed on the thermal oxide film 22 by a CVD process with the thickness of 100-150 nm.

Next, in the step of FIG. 2B, the nitride film 23 is patterned by a photolithographic process while using a resist pattern not illustrated, and there is formed an opening corresponding to the device isolation trench to be formed. Further, by patterning the thermal oxide film 22 and the underlying silicon substrate 21 while using the nitride film 23 thus patterned as a hard mask, there is formed a device isolation trench 21A in the silicon substrate 21 with the width of 100-140 nm and the depth of 260-360 nm as measured from the surface of the silicon substrate 21.

Further, with the step of FIG. 2B, there is formed a thermal oxide liner film 21a on the surface of the device isolation trench 21A thus formed by a thermal oxidation process with the thickness of about 10 nm.

Next, in the step of FIG. 2C, an oxide film 24 is deposited on the structure of FIG. 2B by a high-density plasma CVD process such that the oxide film 24 fills the device isolation trench 21A, and the part of the oxide film 24 deposited on the nitride film 23 is removed by a CMP process. With this, there is formed a device isolation insulator 24A inside the device isolation trench 21A by the foregoing oxide film 24.

Next, in the step of FIG. 2E, the nitride film 23 is removed by a pyrophosphoric acid bath, and the thermal oxide film 22 on the silicon substrate 21 is removed in the step of FIG. 2F by an HF bath. In the example of FIG. 2E, the protruding part of the device isolation insulator 24A protruding beyond the surface of the silicon substrate 21 is partially etched with an amount corresponding to the thickness of the thermal oxide film (about 10 nm), and as a result, there is formed a stepped part on the device isolation insulator 24A in correspondence to the surface of the silicon substrate 21. In the state of FIG. 2F, the surface of the silicon substrate 21 is exposed as a result of etching removal of the thermal oxide film 22.

Further, in the step of FIG. 2G, the present embodiment carries out selective epitaxial growth of a silicon layer on the silicon substrate surface exposed in the step of FIG. 2F to form a silicon layer 27 with the thickness of 20-50 nm, such that the projecting part of the device isolation insulator 24A is exposed.

Such a selective epitaxial growth of the silicon layer 27 is conducted under the pressure of 5.32 kPa (40 Torr) at the substrate temperature of 700° C. while supplying an SiH₂Cl₂ gas and an HCl gas with respective flow rates of 80 SCCM and 10 SCCM. In the present embodiment, it should be noted that a baking processing is conducted to the structure of FIG. 2F before the regrowth of the silicon layer 27 at the temperature of 900° C. for 1 minute.

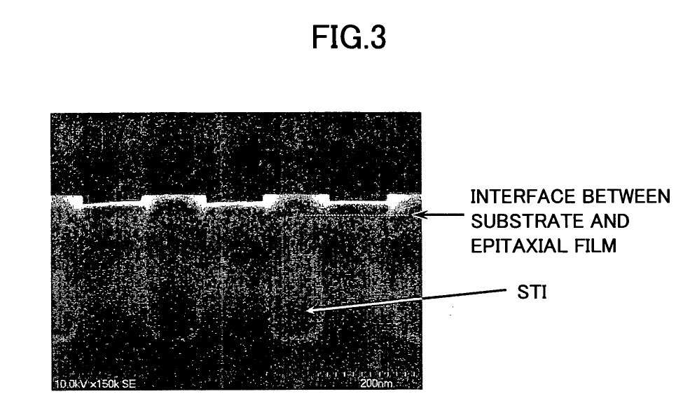

FIG. 3 shows a cross-sectional SEM photograph of the device isolation structure thus obtained.

Referring to FIG. 3, it can be seen that the device isolation film (STI) fills the device isolation trench without forming defects and that there is formed a step in the device isolation insulator in correspondence to the surface of the silicon substrate that serves for the regrowth interface of the silicon layer 27. On the other hand, there is no observable interface between the silicon substrate and the silicon epitaxial layer grown thereon, and the regrowth of the epitaxial layer is observed merely by the existence of the step in the device isolation insulator STI in the SEM observation of FIG. 3.

Thus, according to the present embodiment, the part of the device isolation insulator 24A filling the device isolation trench 21A formed in the nitride film 23 shown in FIG. 2D is used also for an effective device isolation insulator even in such a case in which the aspect ratio of the device isolation trench 21A is suppressed in the step of FIG. 2B so as to avoid formation of void in the CVD oxide film 24 filling the device isolation trench 21A in the step of FIG. 2C, and the part of the device isolation insulator 24A filling the device isolation trench 21A in the nitride film 23 shown in FIG. 2D is used as an effective device isolation insulator by causing regrowth of the silicon layer 27 in the step of FIG. 2G. With this, it becomes possible to realize efficient device isolation even in the case the semiconductor device is a semiconductor integrated circuit having a high integration density

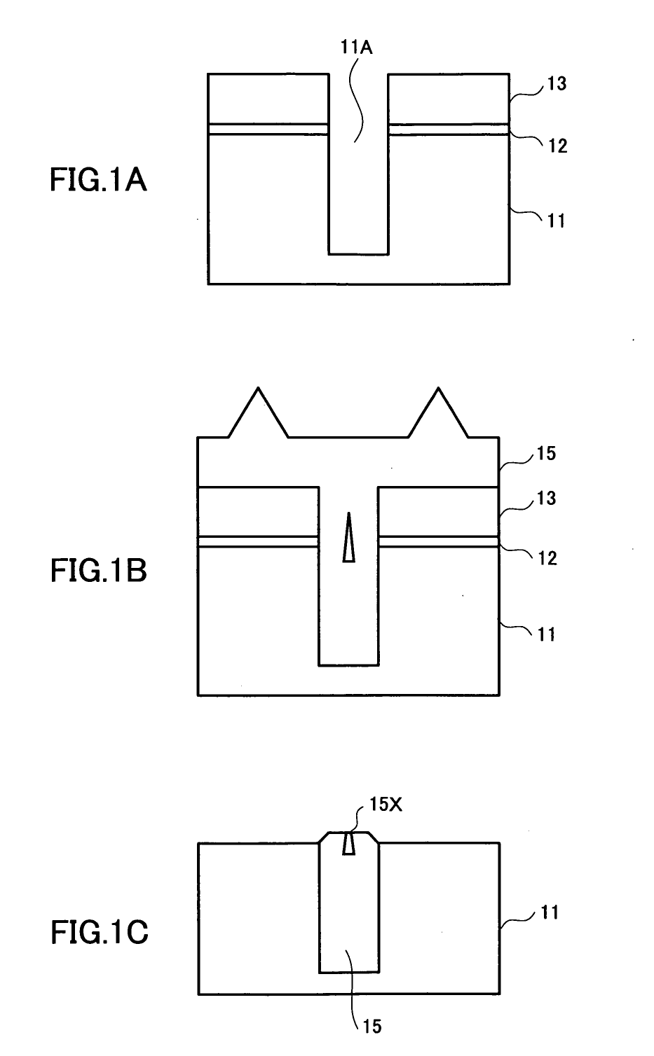

Further, it should be noted that the chance that the void is formed in the part of the CVD oxide film 24 filling the device isolation trench 21A within the nitride film 23 should be small even in such a case in which the device isolation trench 21A formed by the step of FIG. 2B has a large aspect ratio and there can be caused void formation in the CVD oxide film 24 filling the device isolation trench 21A in the step of FIG. 2C. Thus, there is little risk, in the step of FIG. 2G, that the void is exposed in the part of the device isolation insulator 24A from the silicon layer 27, and the problem explained previously with reference to FIG. 1C is successfully avoided.

Thus, according to the present invention, it becomes possible to improve the yield of production of the ultrafine semiconductor device having a very large integration density.

In the step of FIG. 2G, it is also possible to grow a SiGe mixed crystal layer or a SiGeC mixed crystal layer in place of the epitaxial layer 27. In such a case, the interface between the silicon substrate 21 and the epitaxial layer 27 can be detected by detecting the compositional change.

### Second Embodiment

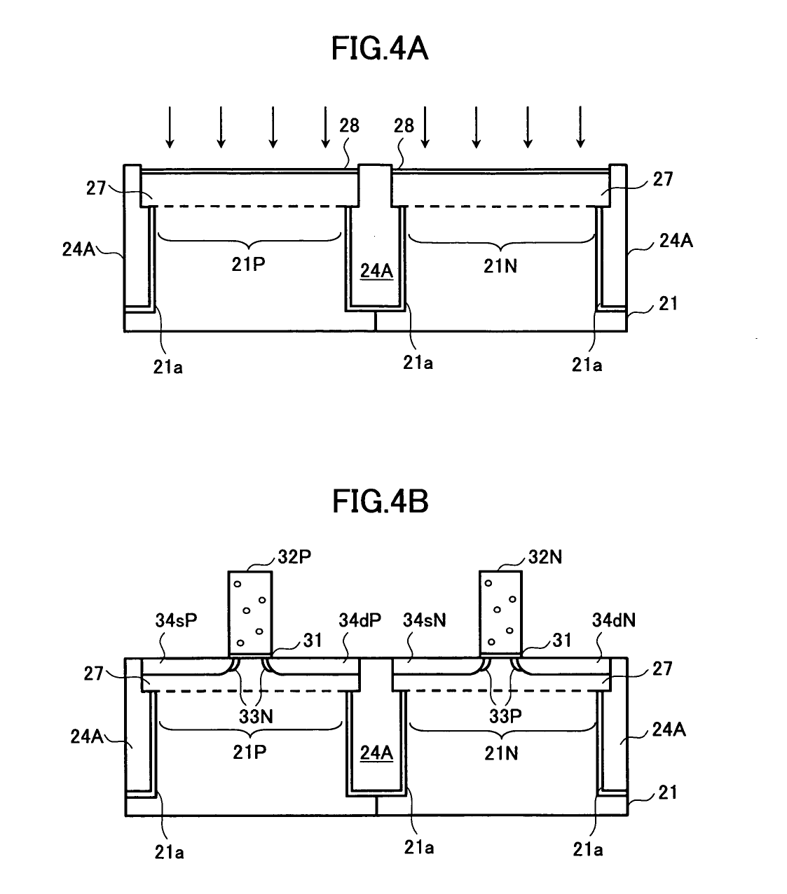

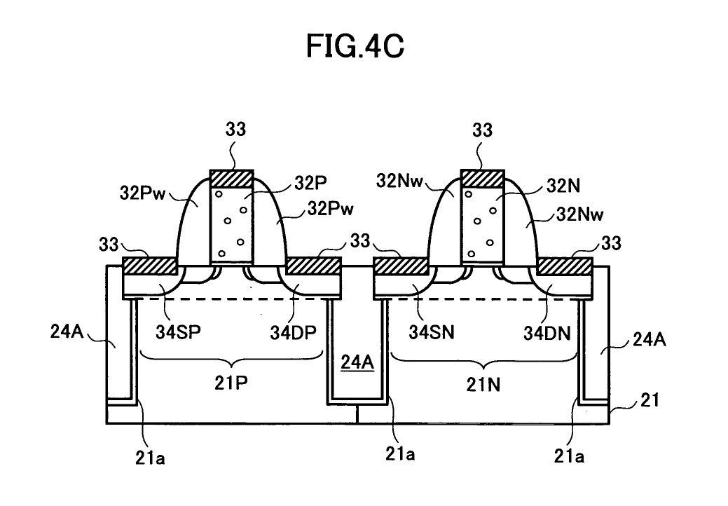

FIGS. 4A-4C show the fabrication process of a CMOS semiconductor integrated circuit device that uses the device isolation structure of FIG. 2G, wherein those parts corresponding to the parts described previously are designated by the same reference numerals and the description thereof will be omitted.

Referring to FIG. 4A, the silicon substrate 21 is formed with an STI device isolation structure including a device isolation insulator 24A formed by the steps of FIGS. 2A-2G explained before. As a result, a device region 21P for a p-channel MOS transistor and a device region 21N for an n-channel MOS transistor are formed in the silicon substrate 21 by a device isolation structure. Further, a silicon epitaxial layer 27 is formed on the silicon substrate 21. As noted with reference to the photograph of FIG. 3, it should be noted that no interface is observed between the silicon substrate 21 and the silicon epitaxial layer 27.

In the step of FIG. 4A, there is formed a thermal oxide film 28 on the surface of the silicon epitaxial layer 27 constituting the device region 21P and the device region 21N with a thickness of about 10 nm as a sacrificial oxide film, and an n-type impurity element and a p-type impurity element are introduced respectively to the device region 21P and the device region 21N separately via the sacrificial oxide film. After thermal activation process of the impurity elements, there is formed an n-type well in the silicon substrate 21 in correspondence to the device region 21P and a p-type well in the silicon substrate in correspondence to the device region 21N.

In the step of FIG. 4a, a thermal oxide having a thickness of about 10 nm is formed on the surface of the silicon epitaxial layer 27 constituting the device region 21P and 21N as a sacrificial oxide film, and an n-type impurity element is introduced into the device region 21P for the formation of an n-type well and an n-type impurity element is introduced into the device region 21P for formation of the channel region separately via the foregoing sacrificial oxide film. Similarly, a p-type impurity element is introduced into the device region 21N for formation of a p-type well and a p-type impurity element is introduced into the device region 21N for formation of the channel region separately via the foregoing sacrificial oxide film. After thermal activation processing, there are formed an n-type well and a channel region in the silicon substrate 21 in correspondence to the device region 21P. Similarly, there are formed a p-type well and a channel region in the silicon substrate 21 in correspondence to the device region 21N.

Further, the sacrificial oxide film 28 is removed in the step of FIG. 4B by a wet etching process, and a high-quality thermal oxide film 31 is formed by a thermal oxidation process as a gate insulation film of the p-channel MOS transistor and the n-channel MOS transistor with a thickness of typically about 2 nm.

Further, in the structure of FIG. 4B, polysilicon patterns 21P and 21N are formed on the gate insulation film 31 respectively in the device region 21P and the device region 21N as the gate electrode of the p-channel MOS transistor and the gate electrode of the n-channel MOS transistor, and a pocket injection region 33N of n-type is formed in the silicon epitaxial layer 27 in correspondence the device region 21P as a result of oblique ion implantation of the n-type impurity element. Similarly, a pocket injection region 33P of p-type is formed in the silicon epitaxial layer 27 in correspondence to the device region 21N as a result of oblique ion implantation of the p-type impurity element.

Further in the device region 21P, there are formed a source extension region 34sP and a drain extension region 34dP in the foregoing silicon epitaxial layer 27 at both lateral sides of the gate electrode 32P by doping of the p-type impurity element. Further, there are formed a source extension region 34sN and a drain extension region 34dN in the silicon epitaxial layer 27 in correspondence to the device region 21N at both lateral directions of the gate electrode 32N by doping of the n-type impurity element.

Further, in the step of FIG. 4C, sidewall insulation films 32Pw and 32Nw are formed on both sidewall surfaces of the gate electrode 32P and the gate electrode 32N respectively, and a source region 34SP and a drain region 34DP of the p-channel MOS transistor are formed by injecting the p-type impurity element into the device region 21P by covering the device region 21N by a resist mask and by using the gate electrode 32P and the sidewall insulation film 32SP as a mask. Further, a source region 32SN and a drain region 32DN of the n-channel MOS transistor is formed by covering the device region 21P by a resist mask (not shown) and injecting the n-type impurity element into the device region 21N while using the gate electrode 32N and the sidewall insulation film 32Nw as a mask.

Further, a metal film of Co or Ni is deposited on the structure thus obtained, and a silicide film 33 is formed on the gate electrodes 32P and 32N and on the source and drain regions 34SP, 34SP, 34SN and 34DN by applying a thermal annealing process. After the thermal annealing process, the metal film remaining unreacted is removed.

With the CMOS device of FIG. 4C, the device regions 21P and 21N thus formed with the p-channel MOS transistor and the n-channel MOS transistor are defined by the STI device isolation structure that includes the device isolation trench 24A, wherein it should be noted that the device isolation trench has a stepped part at the upper part thereof.

Incidentally, in the case a SiGe mixed crystal layer or a SiGeC mixed crystal layer is formed as the epitaxial layer 27 in the step of FIG. 2G, it is possible to detect the interface between the silicon substrate 21 and the epitaxial layer 27 by way of detecting the compositional change.

### Third Embodiment

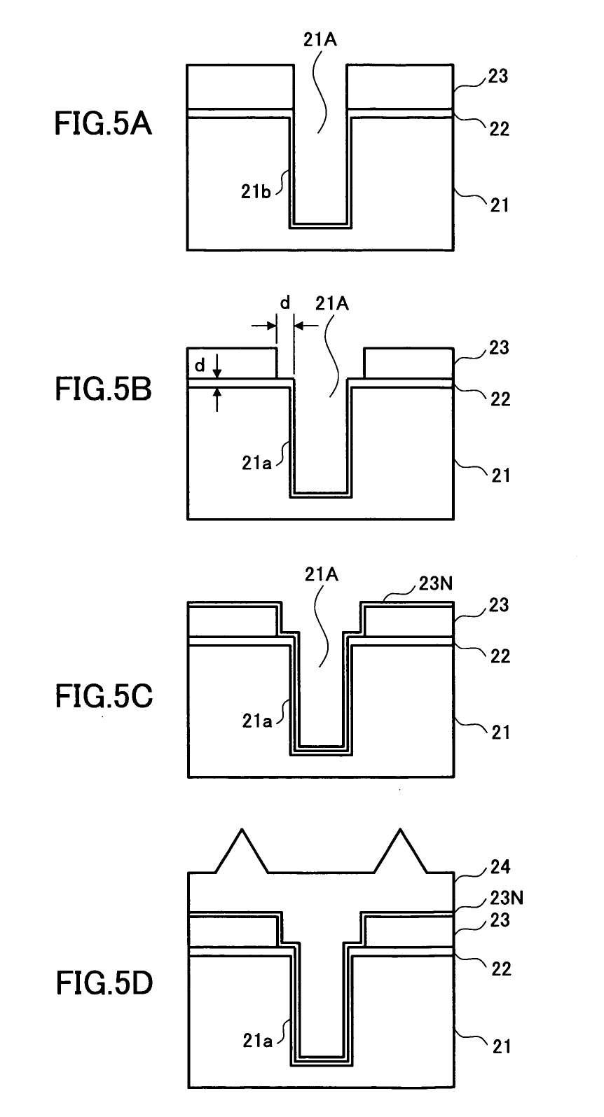

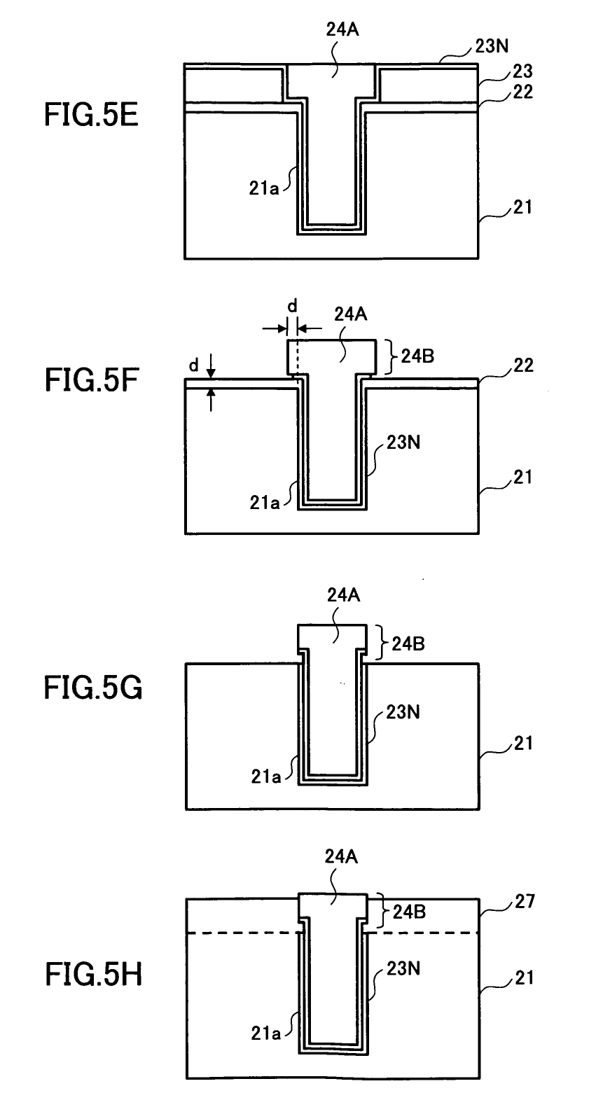

FIGS. 5A-5H are diagrams showing the formation process of the device isolation structure according to the third embodiment of the present invention, wherein those parts corresponding to the parts described previously are designated by the same reference numerals and the description thereof will be omitted.

With the present embodiment, a structure similar to that of FIG. 2B is formed in the step of FIG. 5A, and thus, a thermal oxide film 21b is formed on the surface of the device isolation trench 21A as a protective film with the thickness of about 10 nm.

Next, in the step of FIG. 5B, the nitride film 23 is etched in the lateral direction while using a resist pattern not illustrated as a mask, and with this, the opening formed in the nitride film 23 in correspondence to the device isolation trench 21A is expanded by an amount corresponding to the film thickness d (about 10 nm) of the foregoing sacrificial oxide film 22 as measured from the interface between the thermal oxide film 23a covering the sidewall surface of the device isolation trench 21A and the silicon substrate 21.

Next, in the step of FIG. 5B, the thermal oxide film 21b is removed by a wet etching process, and a liner film corresponding to the thermal oxide liner film 21a of the previous embodiment is formed by a thermal oxidation process with the thickness of about 10 nm.

Next, in the step of FIG. 5C, a nitride film 23N is formed on the structure of FIG. 5B for the purpose of stress relaxation by a CVD process as an inner liner film, and a CVD oxide film corresponding to the CVD oxide film 24 is formed on the structure of FIG. 5C in the step of FIG. 5D by a high-density plasma CVD process so as to fill the device isolation trench 21A.

Further, in the step of FIG. 5E, the part of the CVD oxide film 24 deposited on the nitride film 23N is removed by a chemical mechanical polishing process, and the nitride films 23N and 23 are removed by a wet etching process while using a pyrophosphoric acid solution.

As a result, in the step of FIG. 5F, it should be noted that the device isolation insulator 24A is formed to have an enlarged width lager than the width of the device isolation trench 21A by the foregoing width d in the part 24B on the thermal oxide film 22.

Further, in the step of FIG. 5G, a wet etching process is applied to the structure of FIG. 5F in an HF bath. Thereby, the wet etching process is controlled with regard to the width of the top part 24B such that the sidewall surface of the top part 24B of the device isolation insulator 24A generally coincides with the sidewall surface of the device insulation trench in the silicon substrate 21 and hence the interface between the silicon substrate 21 and the thermal oxide liner film 21a.

With the step of FIG. 5G, it should be noted that the top surface of the silicon substrate 21 is exposed with the removal of the thermal oxide film 22, and thus, the silicon layer 27 is grown epitaxially in the step of FIG. 5H under the condition similar to the one explained with reference to FIG. 2G so that the top part 24B of the device isolation insulator is exposed.

With the device isolation structure thus formed, the top part 24B of the device isolation insulator 24 has a width generally equal to the designed value of the device isolation trench 21A, and it becomes possible to realize the designed device isolation performance.

In the present embodiment, too, there is formed a stepped part at the bottom edge of the foregoing top part 24B of the device isolation insulator 24 as shown in FIG. 5H as a result of the etching of the thermal oxide film 22.

Further, because the width of the foregoing top part 24B is controlled by controlling the wet etching process of FIG. 5G, the sidewall surface of the foregoing top part 24B does not always coincide with the interface between the thermal oxide liner film 21a covering the sidewall surface of the device isolation trench and the silicon substrate 21 exactly. Thus, there can be a case in which the width of the top part 24B may change with respect to the width of the device isolation trench 21A as measured at the foregoing interface, within the range of ±10 nm. Thus, the width of foregoing top part 24B of the device isolation insulator 24 may be larger or smaller than the width of the device isolation trench.

It should be noted that the interface between the silicon epitaxial layer 27 and the silicon substrate 21 cannot be observed even when an electron microscope is used. However, the stepped part formed at the top edge of the thermal oxide linier film 21a by the wet etching process of the thermal oxide film 22 generally corresponds to the location where the interface between the silicon epitaxial layer 27 and the silicon substrate 21 exists.

According to the present embodiment, too, it is also possible to use a SiGe mixed crystal layer or a SiGeC mixed crystal layer for the epitaxial layer in place of the silicon layer.

In the present embodiment, there occurs an increase in the opening formed in the nitride film in correspondence to the device isolation trench in the step of FIG. 5B, and thus, the aspect ratio of the device isolation trench is decreased particularly in this part. Thereby, it becomes possible to achieve deposition of the CVD oxide film 24 in the step of FIG. 5D with excellent step coverage and the film quality is improved at the top part 24B of the device isolation insulator 24 where the film quality provides a profound effect on the performance of the device isolation.

### Fourth Embodiment

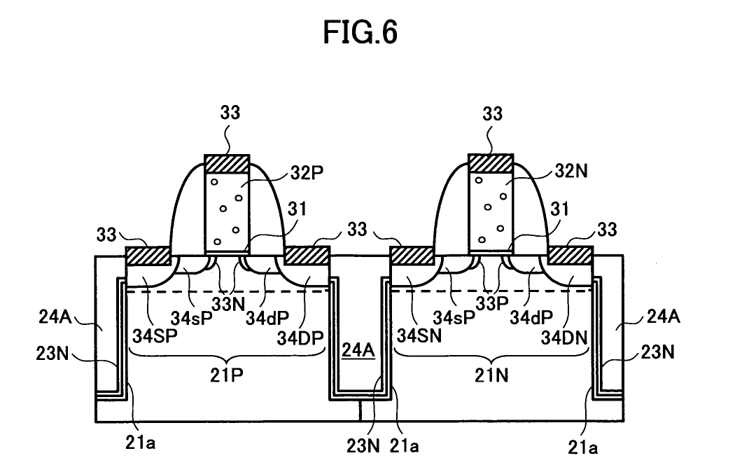

FIG. 6 shows the construction of a CMOS semiconductor integrated circuit device according to a fourth embodiment of the present invention, wherein those parts explained previously are designated by the same reference numerals and the description thereof will be omitted.

Referring to FIG. 6, the present embodiment defines the device region 21P of the p-channel MOS transistor and the device region 21N of the n-channel MOS transistor on the surface of the silicon substrate 21 by the device isolation structure of FIG. 5H, and each of the device regions is formed with the p-channel MOS transistor or n-channel MOS transistor having the construction similar to those of FIG. 4C.

With the use of the device isolation structure, the device isolation insulator 24A includes the thermal oxide film liner 21a and the inner nitride film liner 23N, and there exists an interface of the silicon substrate 21 and the silicon epitaxial layer 27 generally at the top edge of the thermal oxide film liner 21a although not observable.

Similarly to the previous embodiments, existence of such an interface becomes observable when a SiGe mixed crystal layer or SiGeC mixed crystal has been used for the epitaxial layer 27.

### Fifth Embodiment

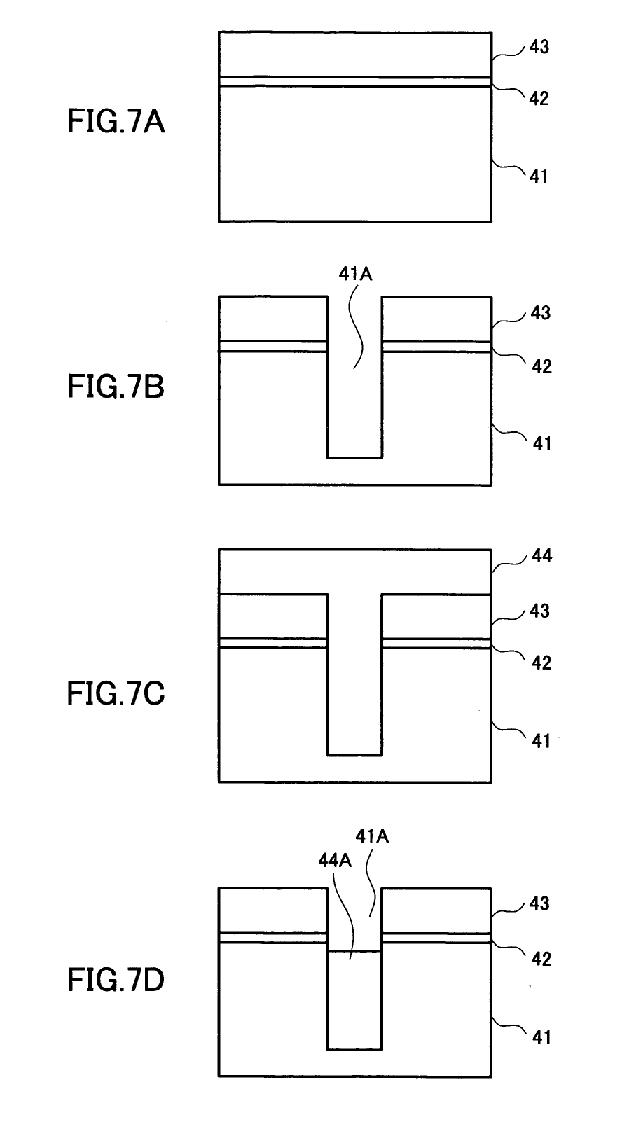

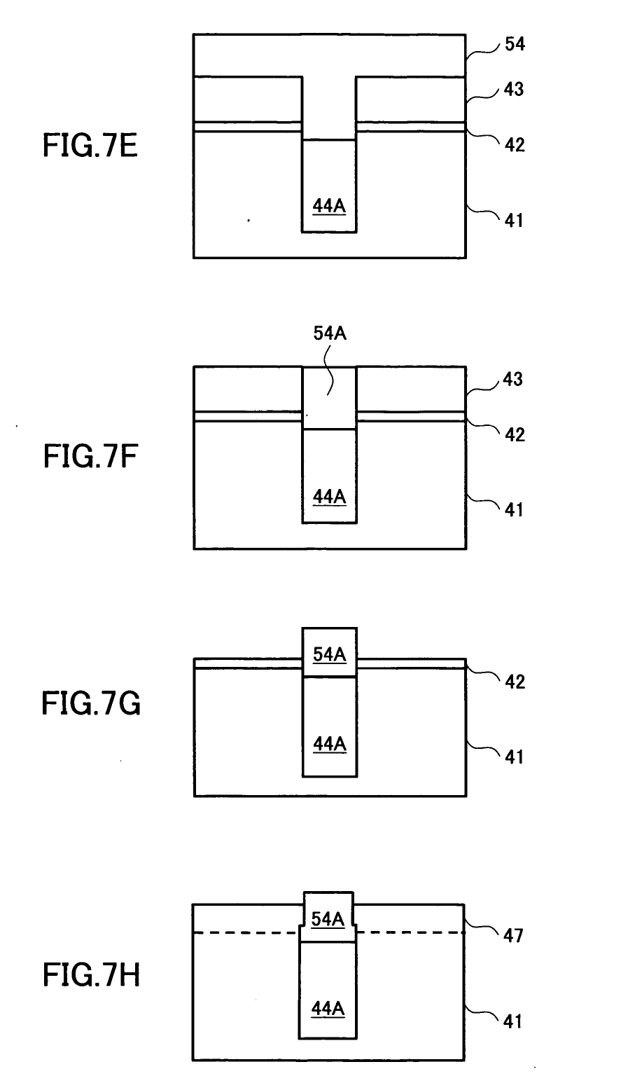

FIGS. 7A-7H show the process of formation of the device isolation structure according to the fifth embodiment of the present invention.

Referring to FIG. 7A, it can be seen that a nitride film 43 is deposited on a silicon substrate 41 via a thermal oxide film 42, and a device isolation trench 41A is formed in the silicon substrate 41 in the step of FIG. 7B by using the nitride film 43 as a hard mask.

Further, in the step of FIG. 7C, the device isolation trench 41A is filled with an oxide film 44 such as a TEOS oxide capable of filling a trench of large aspect ratio, and a device isolation insulator 44A is formed in the step of FIG. 7D by etching back the oxide film 44 on the nitride film 43 such that the device isolation insulator 44A fills the device isolation trench 41A partially.

Further, in the step of FIG. 7E, the device isolation trench 41A thus partially filled with the device isolation insulator 44A is completely filled by depositing a higher quality oxide film (HTO film) 54 by a high-temperature CVD method.

Next, in the step of FIG. 7F, the HTO film 54 is removed by a chemical mechanical polishing process while using the nitride film 43 as a polishing stopper. Thereby, a structure is obtained such that the HTO device isolation insulator 54A fills the device isolation trench 41A over the device isolation insulator 44A. Further, in the step of FIG. 7G, the nitride film 43 is removed by a processing in a pyrophosphoric acid bath.

Further, in the step of FIG. 7H, the structure of FIG. 7G is subjected to a HF wet etching process for removal of the thermal oxide film 42, and a silicon layer 47 is grown epitaxially starting from the exposed surface of the silicon substrate 11. Thereby, a device isolation structure is obtained in which the HTO device isolation insulator 54A is embedded in the silicon epitaxial layer 47.

According to the present embodiment, in which the device isolation insulator filling the device isolation trench is formed first by using a TEOS oxide, or the like, capable of filling a trench of large aspect ratio, and then using a high-quality HTO film, it becomes possible to obtain a high-performance device isolation structure. Thereby, it becomes possible to use substantially the entirety of the HTO film 54 deposited in the step of FIG. 7E with the present embodiment, and it becomes possible to planarize the HTO device isolation trench 54A projecting upward on the silicon substrate 41 by growing the silicon layer 47 epitaxially.

Further, the present invention is not limited to the embodiments described heretofore, but various variations and modifications may be made without departing from the scope of the invention.

What is claimed is:

1. A semiconductor device, comprising:
a substrate;
a device isolation structure formed in said substrate so as to define a device region; and
a semiconductor device formed in said device region,
wherein said device isolation structure comprises a device isolation trench formed in said substrate so as to define said device region and a device isolation insulator filling said device isolation trench,
said device isolation insulator comprising a lower part and an upper part,
a stepped part being formed between said lower part and said upper part.

2. The semiconductor device as claimed in claim 1, wherein said upper part has a smaller width as compared with said lower part.

3. The semiconductor device as claimed in claim 1, wherein said upper part has a larger width as compared with said lower part.

4. The semiconductor device as claimed in claim 1, wherein said step has a step height of 10 nm or less.

5. The semiconductor device as claimed in claim 1, wherein said upper part has a height of 20-50 nm.

6. The semiconductor device as claimed in claim 1, wherein said lower part has a height of 260-360 nm.

7. The semiconductor device as claimed in claim 1, wherein said device isolation insulator has an aspect ratio of 3 or more.

8. The semiconductor device as claimed in claim 1, wherein said device isolation insulator comprises a thermal oxide liner covering a sidewall surface and a bottom surface of said device isolation trench and a CVD oxide film filling an inner side of said thermal oxide liner.

9. The semiconductor device as claimed in claim 1, wherein said device isolation insulator comprises a thermal oxide liner covering a sidewall surface and a bottom surface of said device isolation trench and a nitride film liner formed at an inner side of said thermal oxide film, an inner side of said nitride film liner being filled with a CVD oxide film.

10. The semiconductor device as claimed in claim 1, wherein said semiconductor device has a gate length of 60 nm or less.

11. The semiconductor device as claimed in, claim 1, wherein said substrate comprises a silicon substrate holding said lower part of said device isolation insulator and an epitaxial layer grown on said silicon substrate, said epitaxial layer holding said upper part of said device isolation insulator.

12. The semiconductor device as claimed in claim 11, wherein said epitaxial layer contains Si and Ge.

13. The semiconductor device as claimed in claim 11, wherein said epitaxial layer contains Si and Ge and C.

14. The semiconductor device as claimed in claim 1, wherein said device isolation insulator comprises a first part having a first composition and a second part formed on said first part and having a second composition.

15. A method of fabricating a semiconductor device, comprising the steps of:
forming a mask pattern of a first insulation film having an opening on a semiconductor substrate and forming a device isolation trench in said semiconductor substrate in correspondence to said opening while using said mask pattern as a mask;
depositing a second insulation film on said mask pattern so as to fill said device isolation trench;
removing said second insulation film by a chemical mechanical polishing process until said first insulation film is exposed and forming a device isolation insulator by said second insulation film remaining in said device isolation trench;
exposing a surface of said semiconductor substrate by removing said mask pattern; and
growing a semiconductor layer epitaxially on said exposed surface of said semiconductor substrate.

16. The method as claimed in claim 15, wherein said step of growing said semiconductor layer is conducted such that a top part of said device isolation insulator is exposed from said semiconductor layer.

17. The method as claimed in claim 15, further comprising, after said step of forming said device isolation trench but before said step of depositing said second insulation film, the step of increasing a side of said opening formed in said mask pattern.

18. The method as claimed in claim 17, wherein said step of forming said device isolation trench comprises the step of forming a thermal oxide film on a surface of said device isolation trench, and wherein said step of increasing the size of said opening increases the size of said opening by an amount of a thickness of said thermal oxide film.

19. The semiconductor device as claimed in claim 18, wherein said step of removing said mask pattern further comprises the step of etching a protruding part of said device isolation insulator protruding from a surface of said semiconductor substrate, said step of etching is conducted such that a width of said protruding part becomes generally equal to a width of said device isolation trench.
